(19) United States
(12) Patent Application Publication
(10) Pub. No.: US 2018/0242484 A1
(43) Pub. Date: Aug. 23, 2018

(54) COMPONENT QUANTITY SYSTEM FOR ELECTRONIC COMPONENT TAPE REELS

(71) Applicant: Douglas Robinson, Philomath, OR (US)

(72) Inventor: Douglas Robinson, Philomath, OR (US)

(21) Appl. No.: 15/908,746

(22) Filed: Feb. 28, 2018

Related U.S. Application Data
(63) Continuation of application No. 62/460,877, filed on Feb. 20, 2017.

(51) Int. Cl. H05K 13/04; H05K 13/02; B65H 18/28

(52) U.S. Cl. CPC H05K 13/0417; B65H 18/28; H05K 13/02

(57) ABSTRACT

An improved electronic component holder of the type having a reel of tape, wherein the tape has a back side, a front side, and may include small wells evenly spaced from each other and containing electronic components The improvement includes markings on one of the back side and the front side of the reel of tape containing the electronic components with a scale that will ultimately determine an amount of electronic components left on the reel of tape. The markings may include a means of determining quantity of components on a tape or length of tape by automatic identification or machine vision. The markings may be applied to tapes on reels containing components or to each piece of the component tape assembly, for example the cover tape or component tape, individually such as in a tape pre-print assembly on a newly manufactured cover tape reel.

### CROSS REFERENCE TO RELATED APPLICATIONS

The instant non-provisional patent applications claims priority from provisional patent application No. 62/460,877, filed on Feb. 20, 2017, by Douglas Robinson, for a COMPONENT QUANTITY SYSTEM FOR ELECTRONIC COMPONENT TAPE REELS, and is incorporated herein in its entirety by reference thereto.

### BACKGROUND OF THE INVENTION

### Field of the Invention

The embodiments of the present invention relate to electronic component tape reels, and more particularly, the embodiments of the present invention relate to innovations for marking electronic component tape reels to assess remaining quantity of components left in the reel, innovations for determining a true quantity of components left on the reel used in electronic manufacturing, innovations for marking electronic component tape reels to assess remaining quantity of components in the reel, innovations of using a scale or other marks that can ultimately determine the remaining length of a tape reel without the use of external machines, reel-to-reel counters, hand-held devices, or X-Ray technologies, and innovations for marking electronic component tape reels with a human readable, visible, mark that can be used to ultimately determine remaining length of the tape on the reel.

### Description of the Prior Art

A reel of tape consists of two pieces. A front tape or component tape that has the wells where the components fit into, and a cover tape that bonds to the component tape by being pressure sensitive or thermally applied. The complete assembly of component tape, components, and cover tape is referred to as component tape in the industry. Electronic components including integrated circuits, resistors, capacitors, and other components are arranged onto reels of tape in such a way as they can be easily interfaced to an automated electronic assembly machine. The components are usually contained in small wells or affixed to the tape in even spacing so as to make it easy for the machine to remove the component from the tape and insert onto the electronic assembly.

Thus, to represent this diagrammatically, kindly refer now to the figures of the drawing, and particularly to FIGS. 1 and 2 where the reel of tape of the prior art is shown generally at 10. The reel of tape 10 includes a reel 14 and a tape 16. The tape 16 is revved around the reel 14 and has a back side 20 and a front side 22. The front side 22 of the tape 16 contains evenly spaced-apart wells 24 that removably contain electronic components 26, respectively, for positioning on electronic equipment.

The problem in many cases, however, is that a production run is completed with a surplus of electronic components 26 still left on the tape 16. The exact amount is difficult to determine as the electronic components 26 may be rejected by the electronic equipment or an unknown quantity may have be on the reel 14 at the beginning of production.

Thus, there exists a need for an innovation for determining a true quantity of electronic components 26 still left on the tape 16.

Numerous innovations for reels of tape containing electronic components have been provided in the prior art, which are adapted to be used. Furthermore, even though these innovations may be suitable for the specific individual purposes to which they address, nevertheless, they would not be suitable for the purposes of the embodiments of the present invention as heretofore described.

### SUMMARY OF THE INVENTION

Thus, an object of the embodiments of the present invention is to provide an improved electronic component holder, which avoids the disadvantages of the prior art.

Briefly stated, another object of the embodiments of the present invention is to provide an improved electronic component holder of the type having a reel of tape, wherein the tape may have a back side, a front side, and small wells evenly spaced from each other and containing electronic components, respectively, so as to make it easy for a machine to remove the electronic components from the reel of tape and insert the electronic components onto an electronic assembly. The improvement includes markings on the back side or the front side of the reel of tape containing the electronic components with a scale that will ultimately determine an amount of electronic components left on the reel of tape. Markings can also include barcode or other AutoID technologies. as well as any mark or printing on the separate component tape, separate cover tape, or the completed assembly.

The novel features considered characteristic of the embodiments of the present invention are set forth in the appended claims. The embodiments of the present invention themselves, however, both as to their construction and to their method of operation together with additional objects and advantages thereof will be best understood from the following description of the embodiments of the present invention when read and understood in connection with the accompanying figures of the drawing.

### BRIEF DESCRIPTION OF THE FIGURES OF THE DRAWING

The figures of the drawing are briefly described as follows:

FIG. 1 is a diagrammatic side elevational view of a prior art reel and tape;

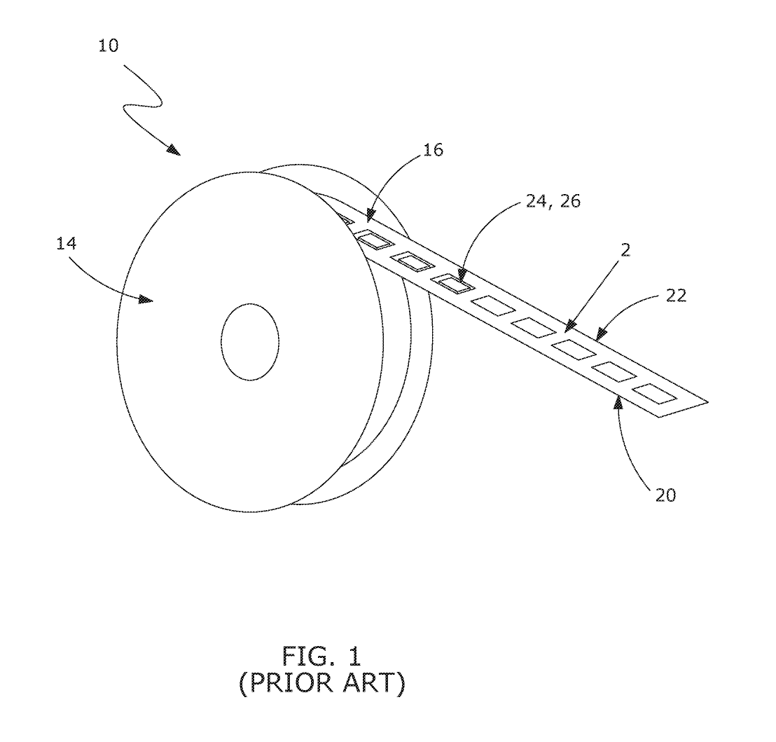

FIG. 2 is an enlarged diagrammatic front side view of a section of the prior art tape of the prior art reel and tape identified by ARROW 2 in FIG. 1; and

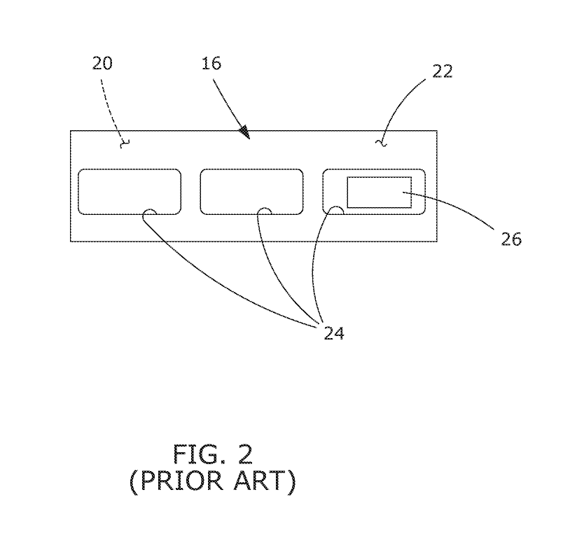

FIG. 3 is a diagrammatic back side view of a section of the tape of the reel and tape of the embodiments of the present invention.

### LIST OF REFERENCE NUMERALS UTILIZED IN THE FIGURES OF THE DRAWING

### Prior Art

10 reel of tape of prior art
14 reel of reel of tape 10 of prior art
16 tape of reel of tape 10 of prior art
20 back side of tape 16 of reel of tape 10 of prior art
22 front side of tape 16 of reel of tape 10 of prior art
24 evenly spaced-apart wells of front side 22 of tape 16 of reel of tape 10 of prior art
26 electronic components of prior art

### Present Invention

30 improved electronic component holder tape of embodiments of present invention
32 markings
33 supplemental tape
34 scale of markings 32
36 ruler of scale 34 of markings 32
38 most inner portion on tape 16 on reel 14
40 low number of most inner portion 38 on tape 16 on reel 14
42 most outer portion on tape 16 on reel 14
44 high number of most outer portion 42 on tape 16 on reel 14
46 remaining length of tape 16 on reel 14

### DETAILED DESCRIPTION OF THE PREFERRED EMBODIMENTS OF THE PRESENT INVENTION

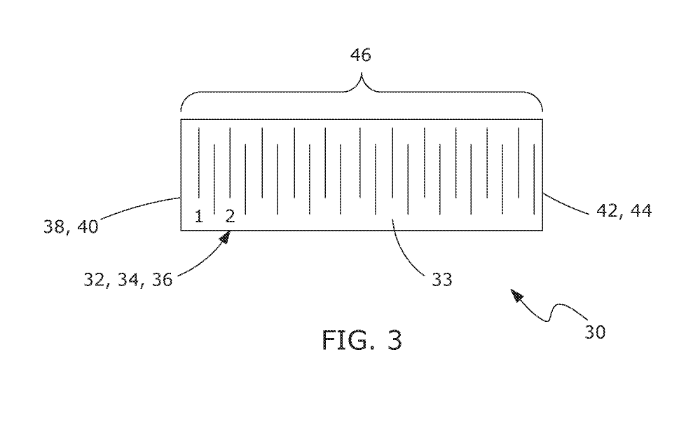

Referring now to FIG. 3, the improved electronic component holder tape of the embodiments of the present invention is shown generally at 30.

The improved electronic component holder tape 30 includes markings 32. The markings 32 are disposed along one of the back side 20 of the tape 16 and the front side 22 of the tape 16. If the markings 32 are disposed along the front side 22 of the tape 16, they are affixed via a supplemental tape 33 that extends adhesively along the front side 22 of the tape 16 and has the markings 32 thereon.

The markings 32 include a scale 34, such as, a ruler 36, which will ultimately determine a length of tape 16 left on the reel 14 by the following operation:
a) A most inner portion 38 on the tape 16 on the reel 14 would be a low number 40;
b) A most outer portion 42 on the tape 16 on the reel 14 would be a high number 44;
c) Simple subtraction of the low number 40 from the high number 44 would give a remaining length 46 of the tape 16 on the reel 14;
d) Since the electronic components 26 are evenly spaced-apart, a determination of components per unit length segment can be made;
e) Multiply the remaining length 46 of the tape 16 on the reel 14 by the components per unit length segment will yield the number of electronic components 26 remaining on the reel 14.

The marking 32 on one of the back side 20 of the tape 16 and the front side 22 of the tape 16 can be made by any method that produces a visible image. This may include offset printing, ink jet printing, flexo printing, laser markings, or any other technology that produces the visible image.

The embodiments of the present invention 30 will aid in determining the true quantity of electronic components 26 left on the reel 14 used in electronic manufacturing.

It is to be understood, however, in the alternative, the markings 32 on the tape may consist of barcodes and or RFID (generally called AutoID).

These barcodes and RFID will contain information that can be retrieved from the tape automatically by appropriate devices, such as, but not limited to, by a barcode reader or an RFID tag reader.

With this arrangement of the barcode and the RFID, the reel quantity is directly inputted into a production control system, and the calculations are processed automatically. It is a way of determining the yield of electronic components 26 remaining on the reel 14 automatically.

### Impressions

It will be understood that each of the elements described above, or two or more together, may also find a useful application in other types of constructions differing from the types described above.

While the embodiments of the present invention have been illustrated and described as embodied in a component quantity system for electronic component tape reels, nevertheless, they are not limited to the details shown, since it will be understood that various omissions, modifications, substitutions, and changes in the forms and details of the embodiments of the present invention illustrated and their operation can be made by those skilled in the art without departing in any way from the spirit of the embodiments of the present invention.

Without further analysis, the foregoing will so fully reveal the gist of the embodiments of the present invention that others can by applying current knowledge readily adapt them for various applications without omitting features that from the standpoint of prior art fairly constitute characteristics of the generic or specific aspects of the embodiments of the present invention.

The invention claimed is:

1. An improved electronic component holder of the type having a reel of tape, wherein the tape has a back side, a front side, and small wells evenly spaced-apart from each other and containing electronic components so as to make it easy for a machine to remove the electronic components from the reel of tape and insert the electronic components onto an electronic component, or a method of affixing electronic components to the tape without the need for wells such as passive components, wherein said improvement comprises:
markings on one of the back side and the front side of the reel of tape containing the electronic components with a scale that will ultimately determine an amount of electronic components left on the reel of tape.

2. The improved electronic component holder of claim 1, wherein the improvement further comprises said markings being a ruler.

3. The improved electronic component holder of claim 1, wherein the improvement further comprises said marking on the one of the back side and the front side of the reel of tape produces visible images.

4. The improved electronic component holder of claim 3, wherein the improvement further comprises the visible images of the markings being offset printing.

5. The improved electronic component holder of claim 3, wherein the improvement further comprises the visible images of the markings being ink jet printing.

6. The improved electronic component holder of claim 3, wherein the improvement further comprises the visible images of the markings being flexo printing.

7. The improved electronic component holder of claim 3, wherein the improvement further comprises the visible images of the markings being laser markings.

8. The improved electronic component holder of claim 1, wherein the improvement further comprises said markings being disposed along one of the back side of the tape and the front side of the tape.

9. The improved electronic component holder of claim 1, wherein the improvement further comprises if said markings are disposed along the front side of the tape, said markings are affix via a supplemental tape that extends adhesively along the front side of the tape and has the markings thereon.

10. The improved electronic component holder of claim 1, wherein the improvement further comprises said markings include a scale, which will ultimately determine a length of tape left on the reel.

11. The improved electronic component holder of claim 10, wherein the improvement further comprises said scale of said markings include a ruler.

12. The improved electronic component holder of claim 1, wherein the improvement further comprises said marking on one of the back side of the tape and on the front side of the tape include offset printing.

13. The improved electronic component holder of claim 1, wherein the improvement further comprises said marking on one of the back side of the tape and on the front side of the tape include ink jet printing.

14. The improved electronic component holder of claim 1, wherein the improvement further comprises said marking on one of the back side of the tape and on the front side of the tape include flexo printing.

15. The improved electronic component holder of claim 1, wherein the improvement further comprises said marking on one of the back side of the tape and on the front side of the tape include laser markings.
